(19) United States
(12) Patent Application Publication
(10) Pub. No.: US 2018/0286766 A1
(43) Pub. Date: Oct. 4, 2018

(54) MANUFACTURING METHOD OF SEMICONDUCTOR DEVICE, SEMICONDUCTOR DEVICE, AND INSPECTION APPARATUS FOR SEMICONDUCTOR DEVICE

(71) Applicant: RENESAS ELECTRONICS CORPORATION, Tokyo (JP)

(72) Inventors: Koji NISHIDA, Tokyo (JP); Toru MOMOTA, Tokyo (JP)

(21) Appl. No.: 15/894,312

(22) Filed: Feb. 12, 2018

(30) Foreign Application Priority Data
Mar. 28, 2017 (JP) 2017-063495

(51) Int. Cl. H01L 21/66; H01L 23/528; H01L 21/78; H01L 23/00; G01R 1/067; G01R 1/073

(52) U.S. Cl. CPC H01L 22/14; H01L 23/528; H01L 21/78; H01L 24/06; G01R 1/06722; G01R 1/07321; H01L 2224/06135; H01L 24/48; H01L 2224/48225; G01R 1/0675

(57) ABSTRACT

In a wafer inspection step for testing electrical characteristics of an integrated circuit in a chip region (CP) formed in a wafer, a first probe needle having a relatively small diameter is brought into contact with a first pad for small current and a second probe needle having a relatively large diameter is brought into contact with a second pad for large current. A wiring and a field effect transistor, which are used for forming the integrated circuit, are arranged directly under the first pad to which a relatively small needle pressure of the first probe needle is to be applied. On the other hand, a wiring and a field effect transistor, which are used for forming the integrated circuit, are not arranged directly under the second pad to which a relatively large needle pressure of the second probe needle is to be applied.

### CROSS-REFERENCE TO RELATED APPLICATIONS

The disclosure of Japanese Patent Application No. 2017-063495 filed on Mar. 28, 2017 including the specification, drawings and abstract is incorporated herein by reference in its entirety.

### BACKGROUND

The present invention relates to a manufacturing method of a semiconductor device, a semiconductor device, and an inspection apparatus technology for a semiconductor device, and, for example, to a manufacturing method of a semiconductor device requiring high integration, a semiconductor device, and a technology that can be effectively applied to an inspection apparatus for a semiconductor device.

For example, Japanese Unexamined Patent Application Publication No. 2000-206148 (Patent Document 1) describes a tester to be used in an inspection step of the manufacturing steps of a semiconductor device. Patent Document 1 discloses a technology in which: a positioning needle is provided in a probe card of a tester in addition to a measuring needle, and the position of the measuring needle and that of a pad of a semiconductor device are aligned by using a needle trace generated when the positioning needle is brought, before the measuring needle is brought into contact with the pad, into contact with the positioning pad.

### RELATED ART DOCUMENT

### Patent Document

[Patent Document 1] Japanese Unexamined Patent Application Publication No. 2000-206148

### SUMMARY

In semiconductor devices, higher functionality and higher performance are required, and higher integration of elements and wirings that form a semiconductor device is being promoted. However, improvement of the degree of integration, obtained by miniaturization of elements and wirings themselves of a semiconductor device, has reached the limit, and various technologies for improving the degree of integration of a semiconductor device are desired also in the manufacturing steps of the semiconductor device.

Other problems and new characteristics will become clear from the description and accompanying drawings of the present specification.

In a manufacturing method of a semiconductor device according to one embodiment, the number of layers, in each of which an integrated circuit pattern for forming an integrated circuit in a semiconductor chip of a semiconductor wafer is arranged, is smaller directly under a second electrode to which a relatively large needle pressure is to be applied from a measuring needle in a wafer inspection step than directly under a first electrode to which a relatively small needle pressure is to be applied from a measuring needle.

In addition, an inspection apparatus for a semiconductor device according to one embodiment includes a first measuring needle that contacts an electrode of a semiconductor chip at a first needle pressure and a second measuring needle that contacts an electrode of the semiconductor chip at a second needle pressure larger than the first needle pressure, in which the thickness of the second measuring needle is set to be larger than that of the first measuring needle.

According to one embodiment, the degree of integration of a semiconductor device can be improved.

### BRIEF DESCRIPTION OF THE DRAWINGS

FIG. 1 is a step chart illustrating manufacturing steps of a semiconductor device according to the present embodiment;

FIG. 2 is a plan view, the left of which is a plan view of a wafer after the wafer processing step in FIG. 1, and the right of which is an enlarged plan view of a chip region formed in the wafer;

FIG. 3 is an enlarged plan view of a bonding pad in FIG. 2;

FIG. 4 shows a sectional view, the left of which is taken along Line I-I in FIG. 3 and the right of which is taken along Line II-II in FIG. 3;

FIG. 5 is an explanatory view illustrating a state where a probe needle of a probe card is pressed against a bonding pad in a chip region of a wafer in the wafer inspection step in FIG. 1;

FIG. 6 is an enlarged explanatory view illustrating a region A1 surrounded by the broken line in FIG. 5;

FIG. 7 is a sectional view, the left of which shows a chip region on the side of a bonding pad to which a relatively large needle pressure is applied from a probe needle during the wafer inspection step of FIG. 6, and the right of which shows a chip region on the side of a bonding pad to which a relatively small needle pressure is applied from a probe needle during the wafer inspection step of FIG. 6;

FIG. 8 is a plan view, the left of which shows a probe needle trace left over a bonding pad to which a relatively large needle pressure is applied from a probe needle, and the right of which shows a probe needle trace left on a bonding pad to which a relatively small needle pressure is applied from a probe needle;

FIG. 9 is a sectional view of the semiconductor device after a packaging step;

FIG. 10 is an enlarged sectional view of a region A2 surrounded by the broken line in FIG. 9;

FIG. 11 is a sectional view of a main part of one example of the wiring layer in FIG. 10;

FIG. 12 is an explanatory view illustrating a schematic configuration example of an inspection apparatus for a semiconductor device in First Embodiment;

FIG. 13 is an explanatory view illustrating a schematic configuration of a probe card of the inspection apparatus of FIG. 12;

FIG. 14 is an enlarged explanatory view illustrating a main part of the probe card in FIG. 13;

FIG. 15 is a sectional view, the left of which shows a chip on the side of a pad to which a relatively large needle pressure is applied from a probe needle during a wafer inspection step in Second Embodiment, and the right of which shows a chip on the side of a pad to which a relatively small needle pressure is applied from a probe needle during the wafer inspection step in Second Embodiment;

FIG. 16 is a sectional view, the left of which shows a chip on the side of a pad to which a relatively large needle pressure is applied from a probe needle during a wafer inspection step in Third embodiment, and the right of which shows a chip on the side of a pad to which a relatively small needle pressure is applied from a probe needle during the wafer inspection step in Third embodiment;

FIG. 17 is an explanatory view illustrating a state before a probe needle of a probe card that forms an inspection apparatus according to Fourth Embodiment is pressed against a bonding pad in a chip region of a wafer;

FIG. 18 is an explanatory view illustrating a state where the probe needle of the probe card in FIG. 17 is pressed against the bonding pad in the chip region of the wafer;

FIG. 19 is a plan view, the left of which shows a probe needle trace left over a bonding pad to which a relatively large needle pressure is applied from a probe needle, and the right of which shows a probe needle trace left over a bonding pad to which a relatively small needle pressure is applied from a probe needle; and

FIG. 20 is a sectional view, the left of which is taken along Line and the right of which is taken along Line IV-IV in FIG. 19.

### DETAILED DESCRIPTION

When necessary for convenience in the following embodiments, description is given by dividing the embodiment into a plurality of sections or embodiments; however, unless expressly stated otherwise, they are not independent of one another, but one is related with part or the whole of another as a variation, a detail, supplementary description, etc.

When the numbers of elements, etc. (including numbers of pieces, numerical values, amounts, ranges, etc.) are referred to in the following embodiments, the numbers are not limited to the specific ones but may be more or less than the specific numbers, unless expressly stated otherwise or except when the numbers are obviously limited to the specific numbers in principle.

Further, in the following embodiments, it is needless to say that the components (also including constituent steps, etc.) are not necessarily requisite unless expressly stated otherwise or except when they are obviously requisite in principle.

Similarly, when referring to the shapes and positional relations, etc., of components, etc., in the following embodiments, unless expressly stated otherwise or except when they can be thought otherwise in principle, those substantially the same or similar to the shapes, etc., are to be included. This also applies to the above numerical values and ranges.

Like components are denoted with like reference numerals in principle in each of the drawings for explaining embodiments, and duplicate descriptions are omitted. In addition, to make drawings easy to understand, even a plan view may be hatched.

### First Embodiment

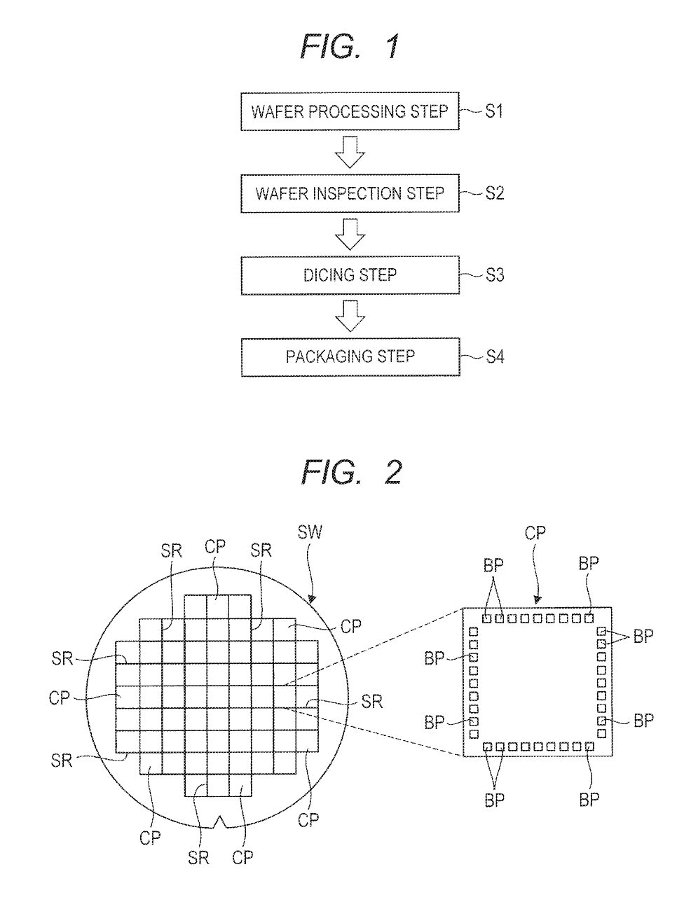

FIG. 1 is a step chart illustrating the manufacturing steps of a semiconductor device according to the present embodiment. One example of a manufacturing method of a semiconductor device according to First Embodiment will be described along the step chart of FIG. 1 and with reference to FIGS. 2 to 9.

The left of FIG. 2 is a plan view of a wafer after a wafer processing step in FIG. 1, and the right thereof is an enlarged plan view of a chip region formed in the wafer. First, a plurality of chip regions CP are formed in a wafer (semiconductor wafer) SW, as illustrated in FIG. 2. That is, an integrated circuit is formed by forming a plurality of elements and wirings in each of the chip regions CP of the wafer SW (S1 in FIG. 1).

The wafer SW is made of, for example, single crystal silicon (Si), and is formed, for example, in a substantially circular shape in plan view. The material of the wafer SW is not limited to single crystal silicon, but can be variously changed, and other semiconductor materials, such as, for example, silicon carbide (SiC), can be used. In addition, an SOI (Silicon On Insulator) substrate or the like, in which a semiconductor layer for forming an element is provided over an insulating layer, can be used as the wafer SW.

A street SR is arranged between the adjacent chip regions CP. The street SR is a boundary region between the adjacent chip regions CP, and has a predetermined width. In each chip region CP, a plurality of bonding pads (hereinafter, simply referred to as pads) BP are arranged. The pad BP is an extraction electrode electrically coupled to an integrated circuit in each chip region CP, and is arranged along and near the outer periphery of the chip region CP in the main surface of the chip region CP. Each pad BP is made of, for example, aluminum, and is formed, for example, in a substantially square shape in plan view. It is noted that the arrangement of the pads BP is not limited to that described above and the pads BP may be arranged, for example, at the center or the like of the main surface of the chip CP.

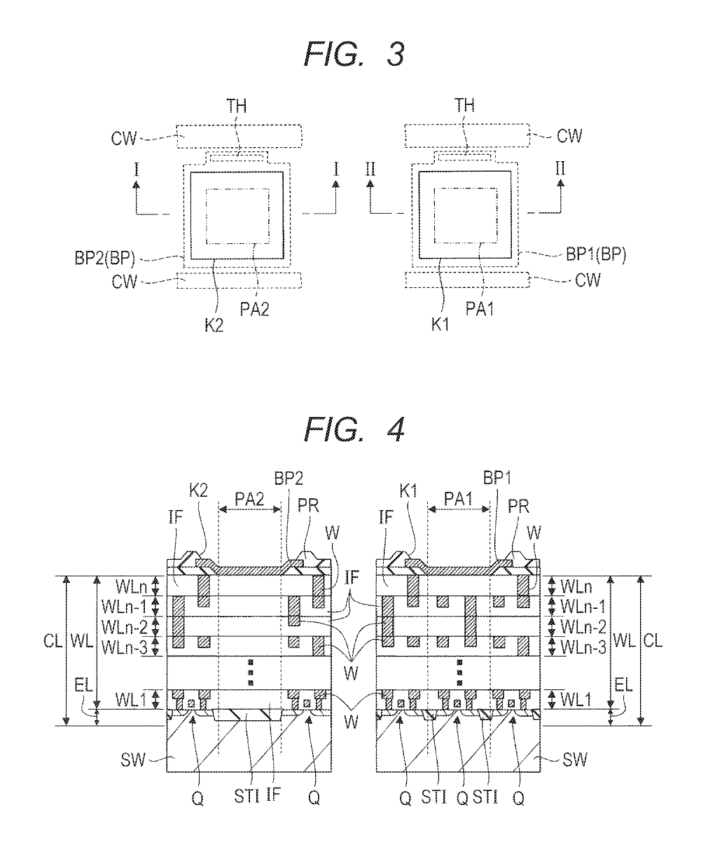

FIG. 3 is an enlarged plan view of the pad in FIG. 2, and the left and right of FIG. 4 are sectional views taken along Line I-I and Line II-II in FIG. 3, respectively. In FIG. 3, the outer shapes of pads BP1 and BP2 are indicated by broken lines. In addition, the sign CW in FIG. 3 indicates part of circulating wiring.

In FIGS. 3 and 4, two types of the pads BP1 and BP2 are illustrated. The pad (first electrode) BP1 is a pad to which a relatively small needle pressure (first needle pressure) is applied from a probe needle during a wafer inspection step S2. On the other hand, the pad (second electrode) BP2 is a pad to which a needle pressure (second needle pressure), which is relatively larger than that applied to the pad BP1, is applied from a probe needle during the wafer inspection step S2.

As an example of using the pads BP1 and BP2, the pad BP1 is a pad corresponding to a small current flowing therethrough, while the pad BP2 is a pad corresponding to a large current flowing therethrough, which is larger than the current flowing through the pad BP1. As another example of using the pads BP1 and BP2, the pad BP1 is a pad for signal, while the pad BP2 is a pad for power supply. The pad for power supply includes a pad for high-potential power supply and a pad for reference potential power supply (e.g., 0 V at the ground (GND) lower than the high-potential power supply.

Openings K1 and K2 are formed in a surface protective film PR in the chip region CP (see FIG. 4). The centers of the upper surfaces of the pads BP1 and BP2 are partially exposed from the respective openings K1 and K2. In the upper surfaces of the pads BP1 and BP2, each of needle pointing regions PA1 and PA2 inside the openings K1 and K2 is a region where a probe needle is applied during the wafer inspection step S2. The needle pointing regions PA1 and PA2 are not actually formed over the pads BP but are recorded as data of an inspection apparatus. The needle pointing regions PA1 and PA2 are set by various parameters such as the alignment accuracy between a probe needle of an inspection apparatus and the pad BP, the diameter of the probe needle, the planar dimension of the pad BP, the planar dimensions of the openings K1 and K2, and the accuracy of forming a pattern in a wafer processing step S1. The sizes of the needle pointing regions PA1 and PA2 are smaller than the planar dimensions of the openings K1 and K2, and are set to be large enough to ensure an alignment margin of the probe needle. The needle pointing regions PA1 and PA2 are located in flat portions of the pads BP1 and BP2.

The outer peripheries of the pads BP1 and BP2 are covered with the surface protective film PR. In each of the pads BP1 and BP2, a through hole TH is arranged in a region covered with the surface protective film PR (located at a position away from each of the needle pointing region PA1 or PA2). Each of the pads BP1 and BP2 is electrically coupled to a wiring W located thereunder through the through hole TH, and is electrically coupled to the above integrated circuit through the wiring W located thereunder. The surface protective film PR is an insulating film for protecting the chip region CP, and is composed of, for example, a silicon oxide film, a silicon nitride film, or a laminated film thereof.

An integrated circuit forming layer CL is formed over the wafer SW, as illustrated in FIG. 4. The integrated circuit forming layer CL is a layer in which an integrated circuit pattern for forming an integrated circuit is arranged, and includes a lowermost element layer EL and a wiring layer WL located thereover.

In the element layer EL, a plurality of elements, such as, for example, field effect transistors (integrated circuit patterns) Q, are formed. However, the elements are not limited to field effect transistors Q, but include various ones, and, for example, active elements, such as bipolar transistors and diodes, and passive elements, such as capacitors and inductors, may be formed. In the element layer EL, for example, a trench type isolation portion STI is formed as an element isolation portion.

The wiring layer WL has a plurality of wiring layers WL1 to WLn−3, WLn−2, WLn−1, and WLn. The wiring (integrated circuit pattern) W and an insulating film IF are formed in each of the wiring layers WL1 to WLn−3, WLn−2, WLn−1, and WLn.

The wiring W is a conductive pattern for forming the above integrated circuit by electrically coupling the elements. Herein, the wiring W includes, for example: a wiring portion extending along the wiring layer; and a coupling portion (via hole portion or plug portion) that crosses (at right angles) the wiring layer to electrically couple the wiring layers or wiring boards. The wiring W is formed by, for example, damascene wiring. The insulating film IF is an insulating member that electrically isolates the wirings W from each other, and is composed of, for example, a silicon oxide film, a silicon nitride film, or a laminated film thereof. Hatching lines in the insulating film IF are omitted to make the view easy to understand.

In First Embodiment, of the integrated circuit forming layer CL, the number of layers in each of which the integrated circuit pattern for forming the integrated circuit is arranged is smaller directly under the pad BP2 (particularly the needle pointing region PA2) to which a relatively large needle pressure is to be applied from a probe needle than directly under the pad BP1 (particularly the needle pointing region PA1) to which a relatively small needle pressure is to be applied from a probe needle.

That is, of the wiring layer WL, the number of the wiring layers in each of which the wirings W for forming the integrated circuit is arranged is smaller directly under the pad BP2 (particularly the needle pointing region PA2) to which a relatively large needle pressure is to be applied from a probe needle than directly under the pad BP1 (particularly the needle pointing region PA1) to which a relatively small needle pressure is to be applied from a probe needle. In other words, of the wiring layer WL, the number of wiring layers in each of which the wiring W for forming the integrated circuit is not arranged is larger directly under the pad BP2 (particularly the needle pointing region PA2) to which a relatively large needle pressure is to be applied from a probe needle than directly under the pad BP1 (particularly the needle pointing region PA1) to which a relatively small needle pressure is to be applied from a probe needle.

As a specific example, directly under the needle pointing region PA1 of the pad BP1 to which a relatively small needle pressure is to be applied from a probe needle, there is neither the restriction that wiring is prohibited for each of the wiring layers WL1 to WLn nor the restriction that the arrangement of an element is prohibited for the element layer EL. Therefore, directly under the needle pointing region PA1 of the pad BP1, for example, the wiring W for forming the integrated circuit is arranged in each of the wiring layers WL1 to WLn, and elements, such as a field effect transistor Q for forming the integrated circuit, are arranged also in the element layer EL located thereunder.

On the other hand, directly under the needle pointing region PA2 of the pad BP2 to which a relatively large needle pressure is to be applied from a probe needle, there are both the restrictions that wiring is prohibited for each of the wiring layers WL1 to WLn and that the arrangement of an element is prohibited for the element layer EL. Therefore, directly under the needle pointing region PA2 of the pad BP2, for example, the wiring W for forming the integrated circuit is never arranged in each of the wiring layers WL1 to WLn and elements for forming the integrated circuit, such as a field effect transistor Q, are not arranged in the element layer EL located thereunder.

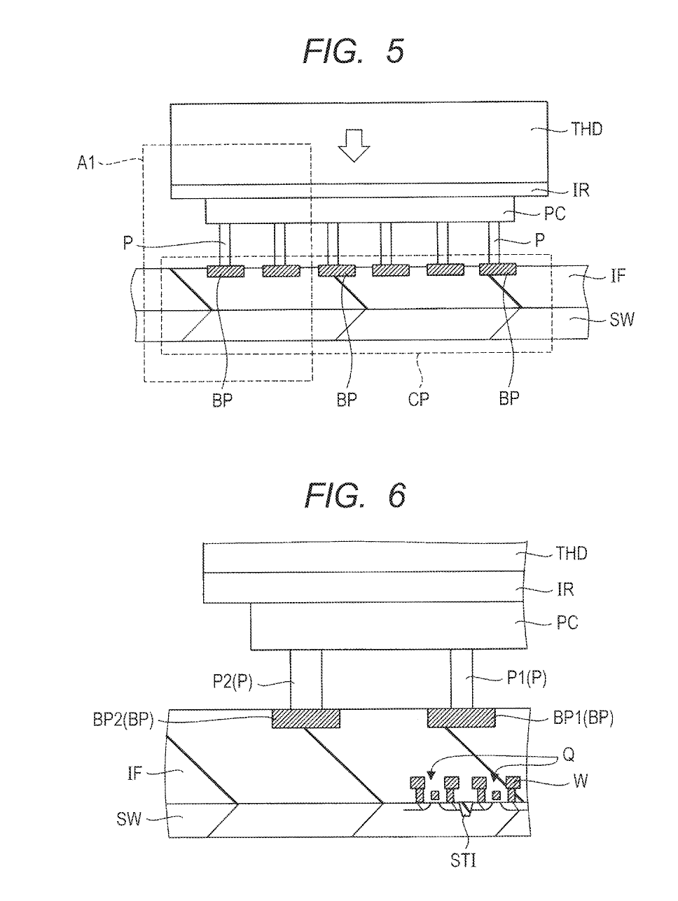

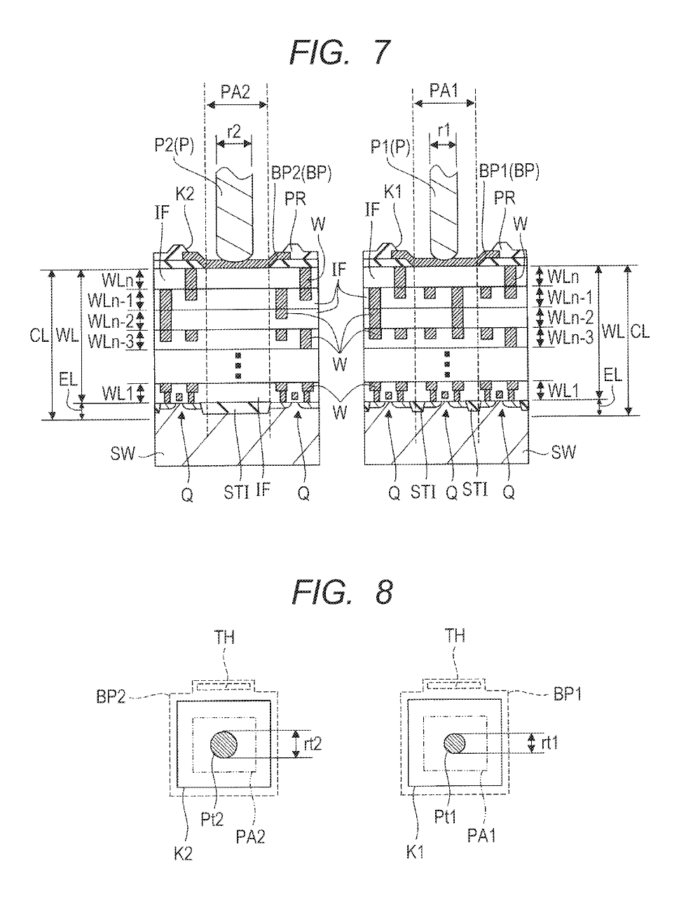

Next, the electrical characteristics of the integrated circuit, formed in each of the chip regions CP of the wafer SW by the above wafer processing step S1, are measured (tested). FIG. 5 is an explanatory view illustrating a state where a probe needle of a probe card is pressed against a pad in the chip region of the wafer in the wafer inspection step in FIG. 1, and FIG. 6 is an enlarged explanatory view illustrating a region A1 surrounded by the broken line in FIG. 5. The left of FIG. 7 is a sectional view of the chip region on the side of a pad to which a relatively large needle pressure is applied from a probe needle during the wafer inspection step of FIG. 6, and the right thereof is a sectional view of the chip region on the side of a pad to which a relatively small needle pressure is applied from a probe needle during the wafer inspection step of FIG. 6.

As illustrated in FIG. 5, a probe card (semiconductor tool) PC is attached to a test head THD that forms the inspection apparatus via an interface ring IR. In the wafer inspection step S2, the electrical characteristics, etc., of the integrated circuit in the chip region CP are measured (tested) in a state where a plurality of probe needles (test terminals) P of the probe card PC are brought into contact with a plurality of pads BP provided in each chip region CP of the wafer SW (S2 in FIG. 1). Non-defective products and defective products of the chip regions CP are selected based on this measurement results. Further, this measurement results are utilized for improving the yield and reliability of a semiconductor device by feeding back them to the wafer processing step S1. For example, a direct current test, an alternating current test, and a function test are performed in the wafer inspection step S2. In the direct current test, for example, the presence or absence of disconnection and short-circuit failure, and the states of input/output voltage and output current are checked. In the alternating current test, for example, the waveform of an output signal is checked. In the function test, for example, an output pattern, availability of data writing, measurement of data retention time, and the presence or absence of data mutual interference are checked. Description of the inspection apparatus including the tester head THD, etc., will be given later.

In semiconductor devices, various specifications for semiconductor devices themselves and inspection apparatuses have been required. For example, a reduction in the size of a chip, an increase in the number of pads, a large current, and the like are required for a semiconductor device. For example, a reduction in pitch, a large increase in current, a low needle pressure, a low resistance, stable contact, and the like are required for a probe card that forms an inspection apparatus.

However, for example, in the technology described in Patent Document 1, the type of a probe card and the specification of a probe are determined by the specification of an electrode (shape (pad/ball), size, pitch, etc.) of the device and all of the probe needles are uniform. Therefore, it is becoming difficult to sufficiently cope with the above various demands.

For example, in the case of a pad requiring a large current or a pad for high-potential power supply, if the contact resistance with a probe needle is large, the potential drops and stable measurement becomes impossible. Also, in the case of a pad for reference potential, if the contact with a probe needle becomes insufficient, potential fluctuation or noise occur, and hence stable measurement becomes impossible. Therefore, it is necessary to firmly bring the probe needle into contact with the pad. However, if the needle pressure of the probe needle is increased in order to improve the contact state between the probe needle and the pad, there is the concern that a portion under the pad may be damaged. So, a configuration in which neither element nor wiring is arranged under the pad can be conceived of, but in the case of Patent Document 1, all of the probe needles are uniform, and hence a large needle pressure is applied from a probe needle to a pad not requiring a large current. Therefore, elements and wirings cannot be arranged under all of the pads, and there is the problem that an improvement in the degree of integration of elements and wirings may be inhibited.

Also, in supplying a large current to a chip region in a wafer inspection step, if the current allowable amount of a probe needle to which the current is to be supplied is smaller than a required current amount, it is configured that the current is supplied from a plurality of probe needles by increasing the number of pads for large current on the chip region side. In this case, however, the number of pads on the chip region side is increased, and hence there is the problem that a reduction in the size of a chip may be inhibited.

Therefore, in First Embodiment, the structure under the pad BP and the specification of the probe needle P of the probe card PC are set in accordance with the pad BP in the chip region CP, in order to achieve the test requirement specification of a semiconductor device. Specifically, a diameter r1 of the probe needle (first measuring needle) P1 requiring a relatively small needle pressure is made smaller, as illustrated in FIGS. 6 and 7. Therefore, a large needle pressure is not applied to the pad BP1 side, and hence it is not necessary to consider a damage to an element or wiring directly under the pad BP1. Therefore, elements (field effect transistor Q, etc.) and the wiring W are arranged directly under the pad BP1 in First Embodiment. Thereby, the degree of integration of elements and wirings of a semiconductor device can be improved more than the case where no element nor wiring is arranged directly under all of the pads BP. Further, the number of regions where elements and wirings can be arranged can be increased in designing the layout of a semiconductor device, and hence the layout design can be easily performed.

On the other hand, a diameter r2 of the probe needle (second measuring needle) P2 requiring a relatively large needle pressure is made larger, as illustrated in FIGS. 6 and 7. That is, the diameter r2 of the probe needle P2 to be brought into contact with the pad BP2 is made larger than the diameter r1 of the probe needle P1 to be brought into contact with the pad BP1. Therefore, the needle pressure of the probe needle P2 for the pad BP2 can be increased. Further, the contact area between the probe needle P2 and the pad BP2 can be increased. Therefore, the contact state between the probe needle P2 and the pad BP2 can be improved. That is, the contact resistance between the probe needle P2 and the pad BP2 can be reduced when the pad BP2 is a pad for large current or for high-potential power supply, and hence a large current or a high-potential power supply can be stably supplied to the integrated circuit in the chip region CP through the pad BP2. Further, the contact resistance between the probe needle P2 and the pad BP2 can be reduced also when the pad BP2 is a pad for reference potential power supply, and hence potential fluctuation or noise generation can be prevented. Therefore, a reference potential can be stably supplied to the integrated circuit in the chip region CP through the pad BP2. Therefore, the inspection accuracy and reliability of the wafer inspection step S2 can be improved, and hence the yield and reliability of a semiconductor device can be improved. Further, a large current can be supplied through one pad BP2, and hence the size of the chip can be reduced more than the case where a plurality of pads for large current are arranged. Therefore, miniaturization of a semiconductor device can be promoted.

However, because a relatively large needle pressure is applied from the probe needle P2 to the pad BP2 side, no element (field effect transistor Q, etc.) nor wiring W is arranged directly under the pad BP2. Thereby, the problem that the elements or wirings directly under the pad BP2 may be damaged when the probe needle P2 is brought into contact with the pad BP2 can be avoided. Therefore, occurrence of a defective semiconductor device caused by the damage can be prevented, and hence the yield and reliability of a semiconductor device can be secured.

Herein, the left of FIG. 8 is a plan view illustrating a probe needle trace left over a pad to which a relatively large needle pressure is applied from a probe needle, and the right thereof is a plan view illustrating a probe needle trace left over a pad to which a relatively small needle pressure is applied from a probe needle. To make the views easy to understand, the probe needle traces Pt1 and Pt2 are hatched.

As described above, the pads BP1 and BP2 are formed of aluminum and are softer than the probe needle P. Therefore, the probe needle trace Pt1 of the thin probe needle P1 is left over the pad BP1, while the probe needle trace Pt2 of the thick probe needle P2 is left over the pad BP2. Because the diameter r2 of the probe needle P2 is larger than the diameter r1 of the probe needle P1, a diameter rt2 of the probe needle trace Pt2 left over the pad BP2 is larger than a diameter rt1 of the probe needle trace Pt1 left over the pad BP1.

Next, after the above wafer inspection step S2, the rotary blade of a dicer is pressed along the street SR of the wafer SW to cut the wafer SW. Thereby, individual chip regions CP are cut out from the wafer SW, and non-defective chips are obtained based on the measurement results in the above wafer inspection step S2 (S3 in FIG. 1).

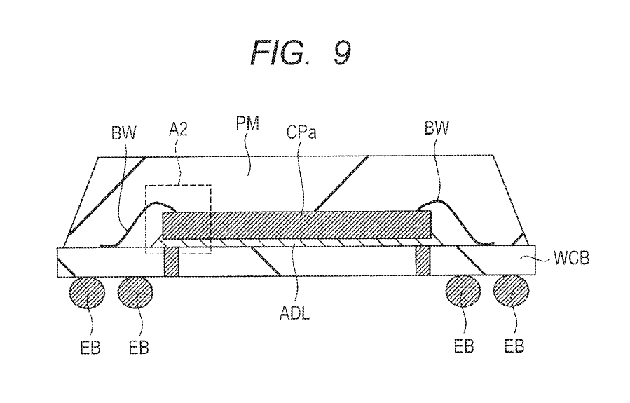

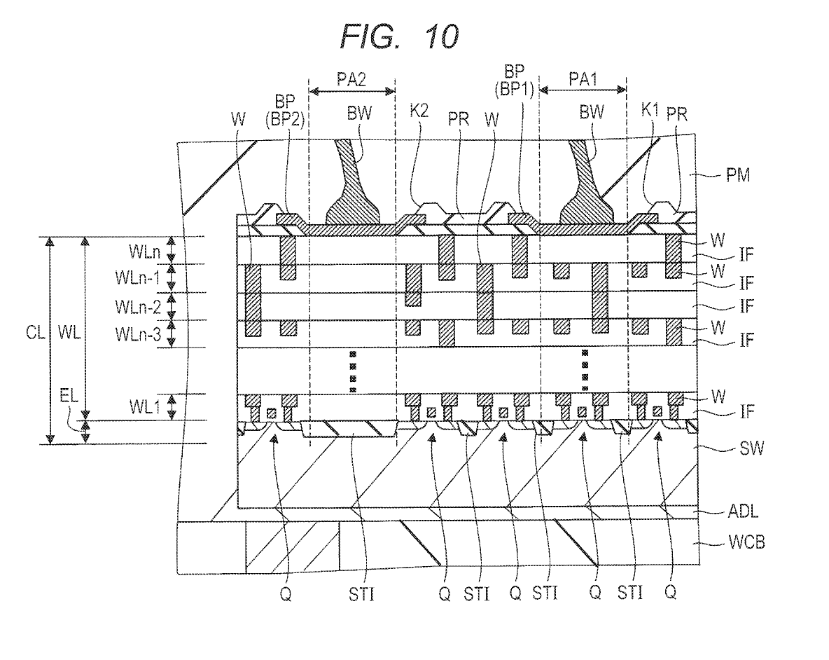

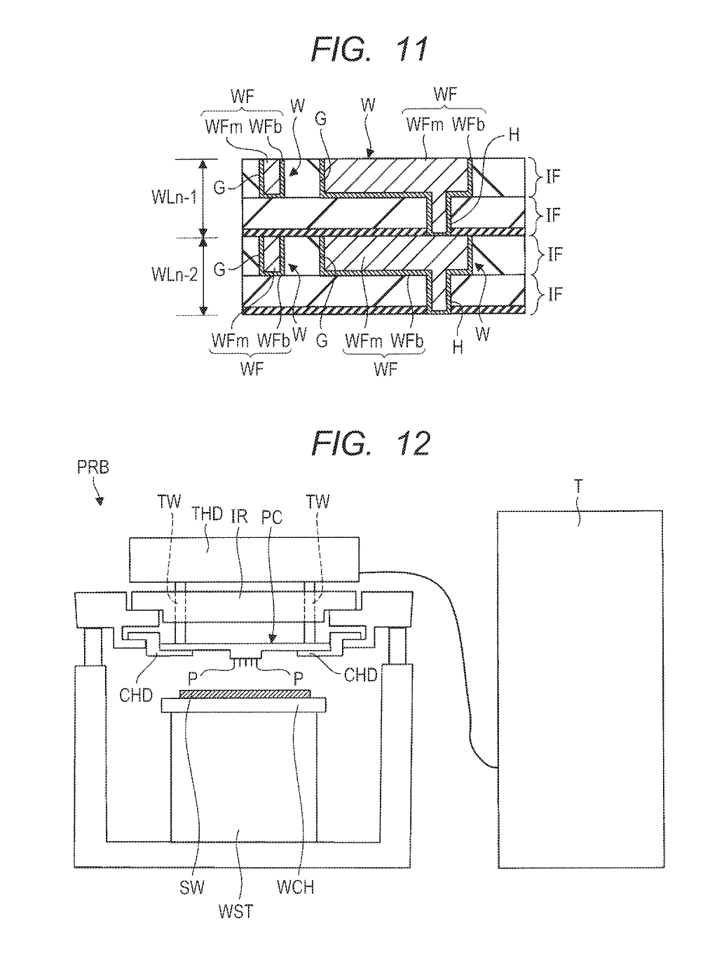

Next, after the dicing step S3, a non-defective chip is mounted over the wiring board and molded with a molding resin or the like (S4 in FIG. 1). FIG. 9 is a sectional view of the semiconductor device after a packaging step, FIG. 10 is an enlarged sectional view of a region A2 surrounded by the broken line in FIG. 9, and FIG. 11 is a sectional view of a main part of one example of the wiring layer in FIG. 10.

A chip CPa is a non-defective chip obtained from the chip region CP (see FIG. 2, etc.), and is mounted, via an adhesive layer ADL, at the center of the main surface of a wiring board WCB and in a state where a surface of the chip, over which the pads BP are to be formed, faces upward, as illustrated in FIG. 9. The pads BP of the chip CPa are electrically coupled to the wiring board WCB through a plurality of bonding wires (hereinafter, simply referred to as wires) BW. The wire BW is formed of, for example, gold (Au) or copper (Cu), and one end of the wire BW is electrically coupled to the pad BP, and the other end thereof is electrically coupled to a wire lead of the wiring board WCB, as illustrated in FIG. 10. This wire lead is electrically coupled to a solder ball EB over the back surface of the wiring board WCB through an inner layer wiring of the wiring board WCB. On the other hand, a sealing member PM formed of, for example, a thermosetting resin is formed over the main surface of the wiring board WCB, and the chip CPa and the wires BW, which are located over the main surface of the wiring board WCB, are covered with the sealing member PM.

Herein, the structures directly under the pads BP1 and BP2 are the same as those described with reference to FIG. 4, as illustrated in FIG. 10. That is, the wiring W and an element (field effect transistor Q) are arranged directly under the needle pointing region PA1 of the pad BP1 to which a relatively small needle pressure is to be applied by the probe needle P1. On the other hand, for example, neither the wiring W nor an element (field effect transistor Q) is arranged directly under the needle pointing region PA2 of the pad BP 2 to which a relatively large needle pressure is to be applied by the probe needle P2.

The wiring W is formed by, for example, damascene wiring, as illustrated in FIG. 11. That is, the wiring W is formed by embedding a conductive film WF (WFm, WFb) in a groove G and a hole H formed in the insulating film IF. The relatively thick conductive film WFm is a main wiring conductive film, and is formed of, for example, copper (Cu). The relatively thin conductive film WFb is a barrier metal film having, for example, a function of preventing diffusion of the copper in the conductive film WFm and a function of improving the adhesion between the conductive film WFm and the insulating film IF, and is provided between the conductive film WFm and the insulating film IF. The conductive film WFb is formed of, for example, titanium (Ti), titanium nitride (TiN), a laminated film thereof, or the like. In the wiring W, a portion embedded in the groove G is the wiring portion described above, and a portion embedded in the hole H is the coupling portion (via hole portion and plug portion) described above.

Next, one example of the inspection apparatus used in the present embodiment will be described with reference to FIGS. 12 to 14. FIG. 12 is an explanatory view illustrating a schematic configuration example of the inspection apparatus for a semiconductor device in the embodiment.

A prober PRB illustrated in FIG. 12 is an inspection apparatus for measuring the electrical characteristics of the integrated circuit formed in each chip region CP of the wafer SW. The wafer SW is placed over a wafer stage WST of the prober PRB in a state where a surface of the chip region CP, over which the pads BP are to be formed, faces upward. A wafer chuck part WCH is provided above the wafer stage WST, and the wafer SW is held (fixed) by an adsorption mechanism and the like of the wafer check part WCH.

An inspection main part including the test head THD, the interface ring IR, a card holder CHD, the probe card PC, and the like is arranged above the wafer stage WST. The test head THD is electrically coupled to a tester T. The tester T is a device for inputting a voltage or a signal necessary for probe inspection to the integrated circuit in the chip region CP to determine the electrical characteristics of the integrated circuit based on the measurement results obtained at that time.

The test head THD and the interface ring IR, and the interface ring IR and the probe card PC are electrically coupled together via a plurality of wirings TW respectively, so that the test head THD and the probe card PC are electrically coupled together. As the wirings TW, a conductive member referred, for example, to a POGO Pin or a spring probe can be used.

Under the interface ring IR, the probe card PC is attached, by the card holder CHD, to the prober PRB in a state where the probe needles P face the wafer SW. Herein, the card holder CHD has a mechanical strength for preventing warpage and the like from occurring in the probe card PC due to the pressure during the wafer inspection step S2.

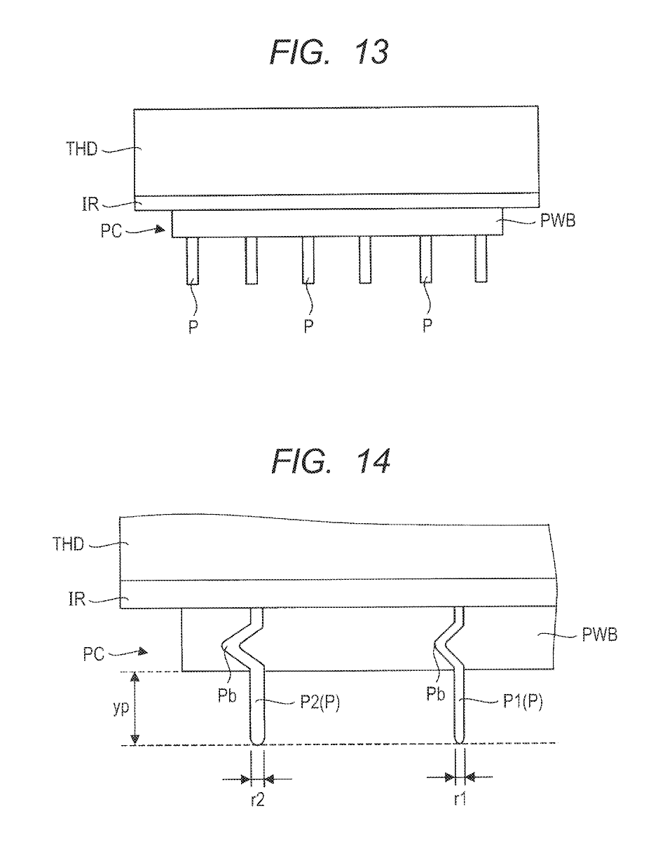

FIG. 13 is an explanatory view illustrating a schematic configuration of the probe card of the inspection apparatus of FIG. 12, and FIG. 14 is an enlarged explanatory view illustrating a main part of the probe card in FIG. 13.

The probe card PC includes a wiring board PWB and the probe needles P (P1, P2) provided over the wiring board PWB. Each probe needle P is formed of, for example, a copper alloy, a palladium alloy, or the like. One end side (tip side) of each probe needle P is provided to protrude substantially perpendicularly toward the wafer SW from the back surface (the surface facing the wafer SW) of the wiring board PWB.

On the other hand, the other end side (leg side) of each probe needle P is electrically coupled to a wiring of the wiring board PWB. That is, the probe needle P is electrically coupled to the test head THD and further to the tester T through the wiring of the wiring board PWB and the wiring TW. In addition, a bent portion Pb is provided on the other end side (leg side) of each probe needle P, as illustrated in FIG. 14. The bent portion Pb of the probe needle P has a function as a leaf spring, and has a function of finely adjusting the needle pressure applied to the pad BP from the probe needle P when the probe needle P is pressed against the pad BP (at the time of overdrive). Herein, the overdrive means an operation in which the probe needle P is pushed further into the pad BP from the position where the probe needle P first touches the pad BP and accordingly it is pressed against the pad BP.

Further, in the present embodiment, the thickness (diameter r2) of the probe needle P2 to which a relatively large needle pressure is to be applied is larger than the thickness (diameter r1) of the probe needle P1 to which a relatively small needle pressure is to be applied, as described above. Thereby, the needle pressure and contact area of the probe needle P with respect to the pad BP can be changed for each pad BP over the chip region CP. In this example, protrusion lengths yp of all of the probe needles P are substantially equal to each other. The protrusion length yp of the probe needle P is the length that the probe needle P protrudes from the back surface of the probe card PC, that is, the length from the back surface (the surface facing the wafer SW) of the wiring board PWB to the tip of the probe needle P.

### Second Embodiment

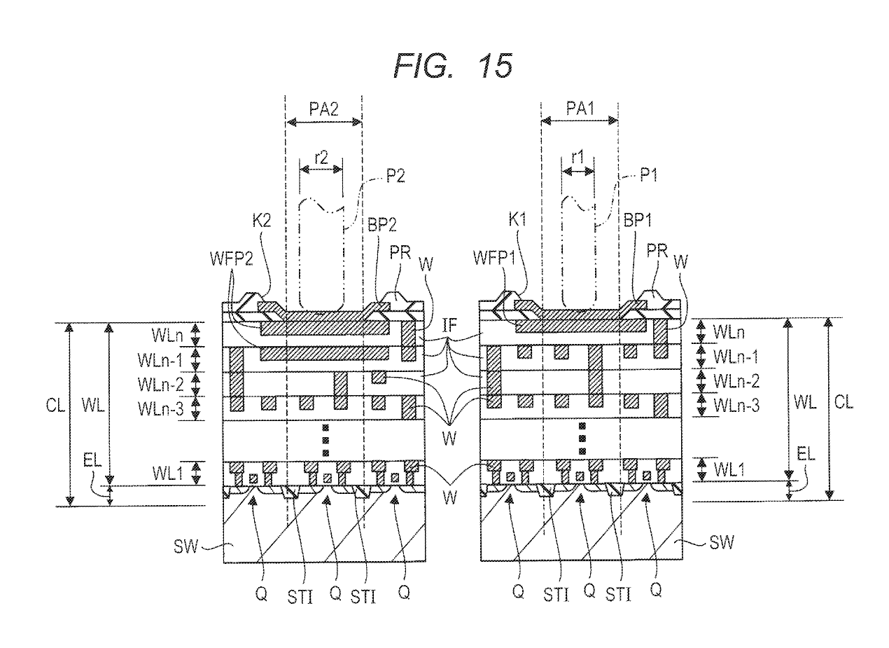

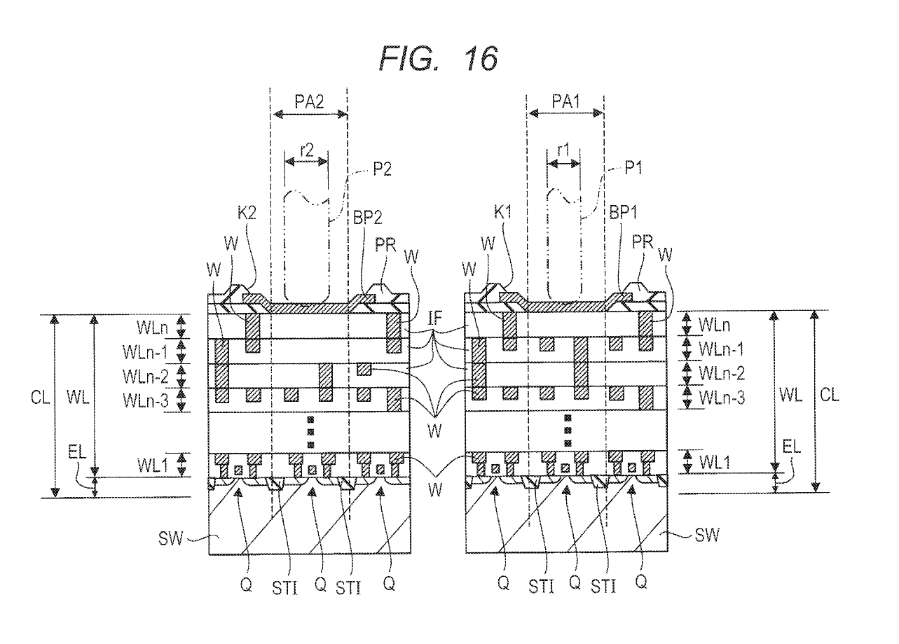

The left of FIG. 15 is a sectional view of a chip on the side of a pad to which a relatively large needle pressure is applied from a probe needle during a wafer inspection step in Second Embodiment; and the right thereof is a sectional view of a chip on the side of a pad to which a relatively small needle pressure is applied from a probe needle during the wafer inspection step.

In Second Embodiment, of the wiring layer WL, the number of the wiring layers in each of which a wiring W for forming an integrated circuit is arranged is smaller directly under the pad BP2 (particularly the needle pointing region PA2) to which a relatively large needle pressure is to be applied from the probe needle P2 than directly under the pad BP1 (particularly the needle pointing region PA1) to which a relatively small needle pressure is to be applied from the probe needle P1, similarly to the above description.

In other words, of the wiring layer WL, the number of wiring layers in each of which the wiring W for forming the integrated circuit is not arranged is larger directly under the pad BP2 (particularly the needle pointing region PA2) to which a relatively large needle pressure is to be applied from the probe needle P2 than directly under the pad BP1 (particularly the needle pointing region PA1) to which a relatively small needle pressure is to be applied from the probe needle P1.

As a specific example, directly under the needle pointing region PA1 of the pad BP1 to which a relatively small needle pressure is to be applied from the probe needle P1, there is the restriction that wiring is prohibited only for an uppermost wiring layer WLn, and a conductive pattern WFP1 is formed in the uppermost wiring layer WLn. The conductive pattern WFP1 is formed by the conductive film WF (see FIG. 11) for forming the wiring W for forming the integrated circuit, but it is not essential for the operation of the integrated circuit. This is because the pad BP1 is electrically coupled to the integrated circuit via non-illustrated wirings.

The conductive pattern WFP1 is formed, for example, in a rectangular solid pattern or a lattice-like line pattern in plan view so as to be larger than the planar dimension of the needle pointing region PA1 and to planarly overlap the needle pointing region PA1. In addition, the conductive pattern WFP1 is coupled to the pad BP1 located thereover. That is, the needle pointing region PA1 (portion with which the probe needle P1 is to be brought into contact) of the pad BP1 is formed of a laminate of the pad BP1 and the conductive pattern WFP1.

Herein, although the needle pressure to be applied to the pad BP1 from the probe needle P1 is relatively small, the wiring in the uppermost wiring layer WLn directly under the pad BP1 may be damaged. Therefore, in Second Embodiment, the conductive pattern WFP1, which is not essential for the operation of the integrated circuit, is provided in the uppermost wiring layer WLn directly under the pad BP 1. Consequently, even if the conductive pattern WFP1 in the wiring layer WLn directly under the pad BP1 is damaged by the needle pressure from the probe needle P1, the integrated circuit is not influenced at all because the conductive pattern WFP 1 is not essential for the operation of the integrated circuit. Further, the wirings W and elements (field effect transistor Q, etc.) in the layers located under the uppermost wiring layer WLn can also be protected by providing the conductive pattern WFP1. Therefore, the problem that the elements or wirings located under the pad BP1 may be damaged when the probe needle P1 is brought into contact with the pad BP1 can be prevented. Therefore, occurrence of a defective semiconductor device caused by the damage can be prevented, and hence the yield and reliability of a semiconductor device can be improved.

Herein, directly under the needle pointing region PA1 of the pad BP1, the wiring layers WLn−1 to WL1 and the element layer EL, which are located under the uppermost wiring layer WLn, are used for forming the integrated circuit, which are the same as those in First Embodiment, so description thereof will be omitted.

On the other hand, directly under the needle pointing region PA2 of the pad BP2 to which a relatively large needle pressure is to be applied from the probe needle P2, there is the restriction that wiring is prohibited for the uppermost wiring layer WLn and the wiring layer WLn−1 located directly thereunder, and conductive patterns WFP2 are formed in the wiring layers WLn and WLn−1. Each of the conductive patterns WFP2 in the wiring layers WLn and WLn−1 is formed by the conductive film WF (see FIG. 11) for forming the wiring W, but it is a conductive pattern not essential for the operation of the integrated circuit, or is electrically isolated (insulated) from the integrated circuit of a semiconductor device. That is, the number of the wiring layers in each of which a conductive pattern not to be used as a wiring for forming the integrated circuit is arranged is larger directly under the pad BP2 than directly under the pad BP1.

The conductive pattern WFP2 is formed, for example, in a rectangular solid pattern or a lattice-like line pattern in plan view so as to be larger than the planar dimension of the needle pointing region PA2 and to planarly overlap the needle pointing region PA2. In addition, the conductive pattern WFP2 in the uppermost wiring layer WLn is coupled to the pad BP2 located thereover. That is, the needle pointing region PA2 (portion with which the probe needle P2 is to be brought into contact) of the pad BP2 is formed of a laminate of the pad BP2 and the conductive pattern WFP2.

Because the needle pressure to be applied to the pad BP2 from the probe needle P2 is relatively large, the wirings W and elements under the pad BP2 may be damaged. Therefore, in Second Embodiment, a conductive pattern not essential for the operation of the integrated circuit and the conductive pattern WFP2 not electrically coupled to the integrated circuit are provided in the two wiring layers WLn and WLn−1 located under the pad BP2. As a result, even if the conductive patterns WFP2 in the two wiring layers WLn and WLn−1 located under the pad BP2 may be damaged due to the needle pressure from the probe needle P2, the integrated circuit is not influenced at all because the conductive pattern WFP2 is not essential for the operation of the integrated circuit or is not electrically coupled to the integrated circuit. Further, the wirings W and elements (field effect transistor Q, etc.), which are located under the wiring layer WLn−1, can also be protected by providing the conductive patterns WFP2 in the two wiring layers WLn and WLn−1. Therefore, the problem that the elements or wirings located under the pad BP2 may be damaged when the probe needle P2 is brought into contact with the pad BP2 can be prevented. Therefore, occurrence of a defective semiconductor device caused by the damage can be prevented, and hence the yield and reliability of a semiconductor device can be improved.

In Second Embodiment, the wirings W for forming the integrated circuit are arranged in the wiring layers WLn−2 to WL1, which are located under the wiring layer WLn−1, directly under the pad BP2 (particularly the needle pointing region PA2). In addition, elements (field effect transistor Q, etc.) for forming the integrated circuit are arranged in the element layer EL directly under the pad BP2 (particularly the needle pointing region PA2). Therefore, the degree of integration of elements and wirings of a semiconductor device can be improved in Embodiment 2 more than in First Embodiment. Further, the easiness of the layout design of elements and wirings of a semiconductor device can be improved more than in First Embodiment. Other advantages are the same as those in First Embodiment. Herein, the case where elements (field effect transistor Q, etc.) for forming the integrated circuit are arranged directly under the pad BP2 has been exemplified, but no element for forming the integrated circuit may be arranged even when the wiring W for forming the integrated circuit is arranged directly under the pad BP2.

Also, in such a case of Second Embodiment, the probe needle traces, left on the pads BP1 and BP2 by the probe needles P1 and P2 in the wafer inspection step S2, are the same as those in FIG. 8 used in First Embodiment, and hence illustration and description thereof will be omitted.

### Third Embodiment

The left of FIG. 16 is a sectional view of a chip on the side of a pad to which a relatively large needle pressure is applied from a probe needle during a wafer inspection step in Third embodiment, and the right thereof is a sectional view of a chip on the side of a pad to which a relatively small needle pressure is applied from a probe needle during the wafer inspection step.

In Third Embodiment, of the wiring layers WL, the number of the wiring layers in each of which the wiring W for forming an integrated circuit is arranged is smaller directly under the pad BP2 (particularly the needle pointing region PA2) to which a relatively large needle pressure is to be applied from the probe needle P2 than directly under the pad BP1 (particularly the needle pointing region PA1) to which a relatively small needle pressure is to be applied from the probe needle P1, similarly to the above description.

In other words, of the wiring layers WL, the number of the wiring layers in each of which the wiring W for forming an integrated circuit is not arranged is larger directly under the pad BP2 (particularly the needle pointing region PA2) to which a relatively large needle pressure is to be applied from the probe needle P2 than directly under the pad BP1 (particularly the needle pointing region PA1) to which a relatively small needle pressure is to be applied from the probe needle P1.

As a specific example, directly under the needle pointing region PA1 of the pad BP1 to which a relatively small needle pressure is to be applied from the probe needle P1, there is the restriction that wiring is prohibited only for the uppermost wiring layer WLn, and neither the wiring W for forming an integrated circuit nor the conductive pattern WFP1 (see FIG. 15) that does not form the integrated circuit is arranged in the uppermost wiring layer WLn.

Although the needle pressure to be applied to the pad BP1 from the probe needle P1 is relatively small, the wiring in the uppermost wiring layer WLn directly under the pad BP1 may be damaged. Therefore, in Third Embodiment, neither the wiring W nor a conductive pattern is arranged in the uppermost wiring layer WLn. Thereby, the problem that the elements or wirings located under the pad BP1 may be damaged when the probe needle P1 is brought into contact with the pad BP1 can be prevented. Therefore, occurrence of a defective semiconductor device caused by the damage can be prevented, and hence the yield and reliability of a semiconductor device can be improved. Herein, directly under the pad BP1, the number of wiring layers in each of which the wiring W for forming an integrated circuit is not provided is not limited to one and can be variously changed, and the number may be two or more depending on the presence or absence of damage.

Directly under the pad BP1 (particularly the needle pointing region PA1), the wiring layers WLn−1 to WL1 and the element layer EL, which are located under the uppermost wiring layer WLn, are used for forming an integrated circuit, which is the same as in First Embodiment and Second Embodiment, and hence description thereof will be omitted.

On the other hand, directly under the needle pointing region PA2 of the pad BP2 to which a relatively large needle pressure is to be applied from the probe needle P2, there is the restriction that wiring is prohibited for the uppermost wiring layer WLn and the wiring layer WLn−1 located directly thereunder. So, neither the wiring W for forming an integrated circuit nor the conductive pattern WFP 2 (see FIG. 15) that does not form the integrated circuit is arranged in the wiring layers WLn and WLn−1. That is, the number of the wiring layers in each of which the wiring W for the integrated circuit is not arranged is larger directly under the pad BP2 than directly under the pad BP1.

Because the needle pressure o be applied to the pad BP2 from the probe needle P2 is relatively large, the wiring W and an element located under the pad BP 2 may be damaged. Therefore, in Third Embodiment, neither the wiring W for forming the integrated circuit nor the conductive pattern WFP2 (see FIG. 15) that does not form the integrated circuit is arranged in the two wiring layers WLn and WLn−1 located under the pad BP2. Therefore, the problem that the elements or wirings located under the pad BP2 may be damaged when the probe needle P2 is brought into contact with the pad BP2 can be prevented. Therefore, occurrence of a defective semiconductor device caused by the damage can be prevented, and hence the yield and reliability of a semiconductor device can be improved. Herein, directly under the pad BP 2, the number of the wiring layers in each of which the wiring W for forming the integrated circuit is not provided is not limited to two and can be variously changed, and the number may be three or more depending on the presence or absence of damage. However, the number of the wiring layers in each of which the wiring W for forming the integrated circuit is not provided is larger directly under the pad BP 2 than directly under the pad BP1.

In Third Embodiment, directly under the pad BP2 (particularly the needle pointing region PA2), the wirings W for forming the integrated circuit are arranged in the wiring layers WLn−2 to WL1 located under the wiring layers WLn and WLn−1. In addition, elements (field effect transistor Q, etc.) for forming the integrated circuit are arranged in the element layer EL directly under the pad BP2 (particularly the needle pointing region PA2). Therefore, the degree of integration of elements and wirings of a semiconductor device can be improved in Third Embodiment more than in First Embodiment. Further, the easiness of the layout design of the elements and wirings of a semiconductor device can be improved more than in First Embodiment. Other advantages are the same as those in First embodiment. Herein, the case where elements (field effect transistor Q, etc.) for forming the integrated circuit are arranged directly under the pad BP2 has been exemplified, but no element for forming the integrated may be arranged even when the wiring W for forming the integrated circuit is arranged directly under the pad BP2.

Also, in such a case of Third Embodiment, the probe needle traces, left over the pads BP1 and BP2 by the probe needles P1 and P2 in the wafer inspection step S2, are the same as those in FIG. 8 used in First Embodiment, and hence illustration and description thereof will be omitted.

### Fourth Embodiment

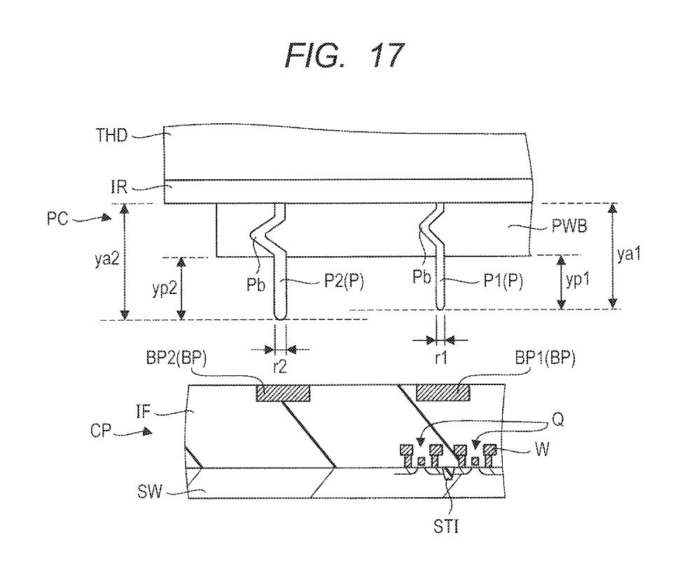

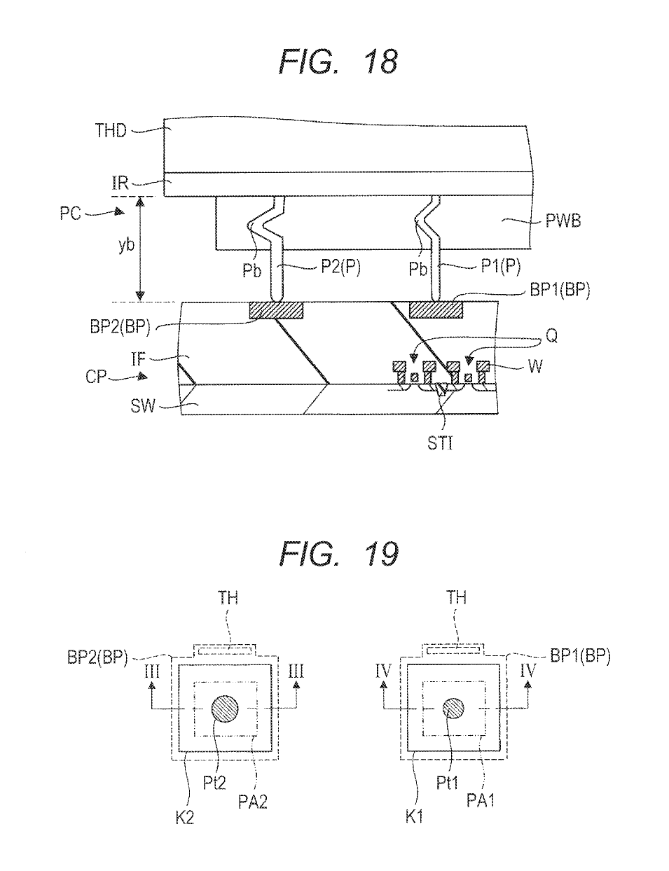

FIG. 17 is an explanatory view illustrating a state before a probe needle of a probe card that forms an inspection apparatus according to Fourth Embodiment is pressed against a pad of a chip of a wafer, and FIG. 18 is an explanatory view illustrating a state where the probe needle of the probe card in FIG. 17 is pressed against the pad of the chip of the wafer.

In Fourth Embodiment, a protrusion length yp2 of the probe needle P2 that applies a relatively large needle pressure to the pad BP2 is larger than a protrusion length yp1 of the probe BP1 that applies a relatively small needle pressure to the pad BP 1, as illustrated in FIG. 17.

The lengths of the probe needles P1 and P2 (lengths from the upper surface of the wiring board PWB to the tips of the probes P1 and P2), occurring before the probe needles P1 and P2 are pressed against the pads BP1 and BP2, are set to ya1 and ya2, respectively, as illustrated in FIG. 17. In addition, the lengths of the probe needles P1 and P2 (lengths from the upper surface of the wiring board PWB to the tips of the probes P1 and P2), occurring when the probe needles P1 and P2 are pressed against the pads BP1 and BP2, are set to yb, respectively, as illustrated in FIG. 18. Then, the stroke length of the probe needle P1 can be expressed as ya1−yb, and that of the probe needle P2 can be expressed as ya2−yb. The stroke length (ya2−yb) of the probe needle P2 is larger than the stroke length (ya1−yb) of the probe needle P1. In addition, the probe needle P2 is thicker than the probe needle P1, similarly to First Embodiment, etc.

In Fourth Embodiment, because the protrusion length yp2 of the probe needle P2 is set to be larger than the protrusion length yp1 of the probe needle P1, the needle pressure to be applied to the pad BP2 from the probe needle P2, which is larger than the needle pressure to be applied to the pad BP1 from the probe needle P1, can be made larger than those in First Embodiment to Third Embodiment. Thereby, the contact state between the probe needle P2 and the pad BP2 can be further improved. Therefore, the contact resistance between the probe needle P2 and the pad BP2 can be further reduced in the wafer inspection step S2, and hence the inspection can be performed in a stable state. Therefore, the accuracy and reliability of a test in the wafer inspection step S2 can be further improved, and hence the yield and reliability of a semiconductor device can be further improved. Herein, the structures described in First Embodiment have been exemplified as the structures under the pads BP1 and BP2 in the chip region CP (chip CPa), but the structures under the pads BP1 and BP2 are not limited thereto, and the structures under the pads BP1 and BP2 in the chip region (chip CPa) may be set to be the same as those described in Second Embodiment and Third Embodiment. Also, the case where the probe needle P2 is thicker than the probe needle P1 has been exemplified herein, however, the thicknesses (diameters) of the probe needle P1 and P2 may be set to be equal to each other, and the protrusion lengths yp1 and yp2 (stroke lengths) may be changed as described above.

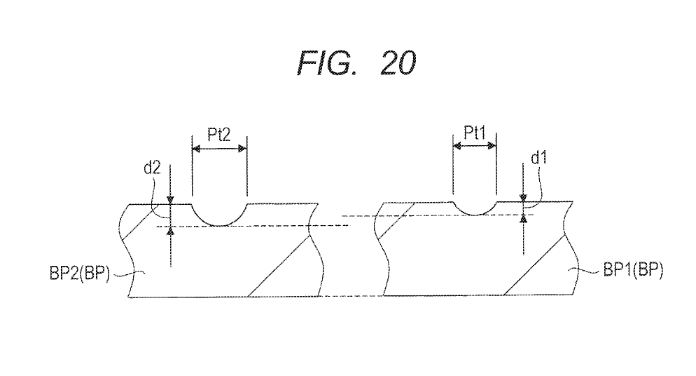

The left of FIG. 19 is a plan view illustrating a probe needle trace left on a pad to which a relatively large needle pressure is applied from a probe needle, the right thereof is a plan view illustrating a probe needle trace left on a pad to which a relatively small needle pressure is applied from a probe needle, and the left and right of FIG. 20 are sectional views taken along Line III-III and Line IV-IV in FIG. 19, respectively. In addition, to make the views easy to understand, the probe needle traces Pt1 and Pt2 are hatched.

Also, in Fourth Embodiment, the diameter r2 of the probe needle P2 is larger than the diameter r1 of the probe needle P1 in the same way as described in FIG. 8, and hence the diameter rt2 of the probe needle trace Pt2 left on the pad BP2 is larger than the diameter rt1 of the probe needle trace Pt1 left on the pad BP1, as illustrated in FIG. 19. In addition, in Fourth Embodiment, a depth d2 of the probe needle trace Pt2 left on the pad BP2 to which a relatively large needle pressure has been applied is larger than a depth d1 of the probe needle trace Pt1 left on the pad BP1 to which a relatively small needle pressure has been applied, as illustrated in FIG. 20.

The invention made by the present inventors has been specifically described above based on its preferred embodiments, but it is needless to say that the invention should not be limited to the embodiments and may be modified variously within a range not departing from the gist thereof.

In addition, some of the contents described in the above embodiments are described below.

### [Supplementary Note 1]

A semiconductor device including:

a plurality of elements formed in a semiconductor chip;

a wiring for forming an integrated circuit by electrically coupling the elements; and

a plurality of electrodes arranged in the semiconductor chip in a state of being electrically coupled to the integrated circuit, in which

the electrodes have a first electrode to be brought into contact with at a first needle pressure and a second electrode to be brought into contact with at a second needle pressure, when the integrated circuit is electrically tested in a state where measuring needles are brought into contact with the electrodes, and in which

the number of layers in each of which an integrated circuit pattern for forming the integrated circuit is arranged is smaller directly under the second electrode than directly under the first electrode.

### [Supplementary Note 2]

The semiconductor device according to Supplementary Note 1, in which

the second electrode is an electrode that allows a current to flow, the current being larger than a current allowed to flow through the first electrode.

### [Supplementary Note 3]

The semiconductor device according to Supplementary Note 1, in which

the first electrode is an electrode for signal and the second electrode is an electrode for power supply.

### [Supplementary Note 4]

An inspection apparatus for a semiconductor device, including a probe card for bringing, when electrical characteristics of an integrated circuit formed in a chip region of a semiconductor wafer are inspected, a plurality of measuring needles into contact with a plurality of electrodes arranged in the chip region in a state where the electrodes are electrically coupled to the integrated circuit, in which

the measuring needles have:

a first measuring needle that contacts a first electrode of the electrodes at a first needle pressure; and

a second measuring needle that contacts a second electrode of the electrodes at a second needle pressure larger than the first needle pressure, and in which

a thickness of the second measuring needle is larger than that of the first measuring needle.

### [Supplementary Note 5]

An inspection apparatus for a semiconductor device, including a probe card for bringing, when electrical characteristics of an integrated circuit formed in a chip region of a semiconductor wafer are inspected, a plurality of measuring needles into contact with a plurality of electrodes arranged in the chip region in a state where the electrodes are electrically coupled to the integrated circuit, in which

the measuring needles have:

a first measuring needle that contacts a first electrode of the electrodes at a first needle pressure; and

a second measuring needle that contacts a second electrode of the electrodes at a second needle pressure larger than the first needle pressure, and in which

a protrusion length of the second measuring needle protruding from the probe card is larger than a protrusion length of the first measuring needle protruding from the probe card.

### [Supplementary Note 6]

An inspection apparatus for a semiconductor device, including a probe card for bringing, when electrical characteristics of an integrated circuit formed in a chip region of a semiconductor wafer are inspected, a plurality of measuring needles into contact with a plurality of electrodes arranged in the chip region in a state where the electrodes are electrically coupled to the integrated circuit, in which

the measuring needles have:

a first measuring needle that contacts a first electrode of the electrodes at a first needle pressure; and

a second measuring needle that contacts a second electrode of the electrodes at a second needle pressure larger than the first needle pressure, and in which

a stroke length of the second measuring needle is larger than that of the first measuring needle.

### [Supplementary Note 7]

The inspection apparatus for a semiconductor device according to Supplementary Note 4, Supplementary Note 5, or Supplementary Note 6, in which

the number of layers in each of which an integrated circuit pattern for forming the integrated circuit is arranged is smaller directly under the second electrode than directly under the first electrode.

What is claimed is:

1. A manufacturing method of a semiconductor device, comprising the steps of:
(a) after an integrated circuit is formed in a chip region of a semiconductor wafer, forming in the chip region a plurality of electrodes electrically coupled to the integrated circuit;
(b) inspecting electrical characteristics of the integrated circuit in a state where a plurality of measuring needles are brought into contact with the electrodes in the chip region; and
(c) after the step (b), cutting the chip region from the semiconductor wafer to form a semiconductor chip,
wherein the step (b) includes the step of testing the electrical characteristics of the integrated circuit in a state where a first measuring needle of the measuring needles is brought into contact with a first electrode of the electrodes at a first needle pressure and a second measuring needle of the measuring needles is brought into contact with a second electrode of the electrodes at a second needle pressure larger than the first needle pressure, and
wherein the number of layers in each of which an integrated circuit pattern for forming the integrated circuit is arranged is smaller directly under the second electrode than directly under the first electrode.

2. The manufacturing method of a semiconductor device according to claim 1,
wherein a wiring as the integrated circuit pattern is arranged directly under the first electrode, and
wherein a wiring as the integrated circuit pattern is not arranged directly under the second electrode.

3. The manufacturing method of a semiconductor device according to claim 2,
wherein an element as the integrated circuit pattern is arranged directly under the first electrode, and
wherein an element as the integrated circuit pattern is not arranged directly under the second electrode.

4. The manufacturing method of a semiconductor device according to claim 1,
wherein the number of wiring layers in each of which a wiring as the integrated circuit pattern is arranged is smaller directly under the second electrode than directly under the first electrode.

5. The manufacturing method of a semiconductor device according to claim 1,
wherein the number of wiring layers in each of which a wiring as the integrated circuit pattern is not arranged is larger directly under the second electrode than directly under the first electrode.

6. The manufacturing method of a semiconductor device according to claim 5,
wherein directly under the second electrode and the first electrode, a wiring layer in which the wiring is not arranged is arranged above a wiring layer in which the wiring is arranged.

7. The manufacturing method of a semiconductor device according to claim 5,
wherein a conductive pattern not electrically coupled to the integrated circuit is arranged in the wiring layer in which the wiring is not arranged, and
wherein the number of wiring layers in each of which the conductive pattern is arranged is larger directly under the second electrode than directly under the first electrode.

8. The manufacturing method of a semiconductor device according to claim 1,
wherein the second electrode is an electrode that allows a current to flow, the current being larger than a current allowed to flow through the first electrode.

9. The manufacturing method of a semiconductor device according to claim 1,
wherein the first electrode is an electrode for signal and the second electrode is an electrode for power supply.

10. The manufacturing method of a semiconductor device according to claim 1,
wherein a thickness of the second measuring needle is larger than that of the first measuring needle.

11. The manufacturing method of a semiconductor device according to claim 10,
wherein a protrusion length of the second measuring needle is larger than that of the first measuring needle.

12. A semiconductor device comprising:
a plurality of elements formed in a semiconductor chip;
a wiring for forming an integrated circuit by electrically coupling the elements; and
a plurality of electrodes arranged in the semiconductor chip in a state of being electrically coupled to the integrated circuit,
wherein the electrodes include a first electrode that is brought into contact with at a first needle pressure and a second electrode that is brought into contact with at a second needle pressure larger than the first needle pressure, those contacts occurring when the integrated circuit is tested in a state where measuring needles are brought into contact with the electrodes, and
wherein the number of layers in each of which an integrated circuit pattern for forming the integrated circuit is arranged is smaller directly under the second electrode than directly under the first electrode.

13. The semiconductor device according to claim 12,
wherein a wiring as the integrated circuit pattern is arranged directly under the first electrode, and
wherein a wiring as the integrated circuit pattern is not arranged directly under the second electrode.

14. The semiconductor device according to claim 13,
wherein an element as the integrated circuit pattern is arranged directly under the first electrode, and
wherein an element as the integrated circuit pattern is not arranged directly under the second electrode.

15. The semiconductor device according to claim 12,
wherein the number of wiring layers in each of which a wiring as the integrated circuit pattern is arranged is smaller directly under the second electrode than directly under the first electrode.

16. The semiconductor device according to claim 12,
wherein the number of wiring layers in each of which a wiring as the integrated circuit pattern is not arranged is larger directly under the second electrode than directly under the first electrode.

17. The semiconductor device according to claim 16,
wherein directly under the second electrode and the first electrode, the wiring layer in which the wiring is not arranged is arranged above a wiring layer in which the wiring is arranged.

18. The semiconductor device according to claim 16,
wherein a conductive pattern not electrically coupled to the integrated circuit is arranged in the wiring layer in which the wiring is not arranged, and
wherein the number of wiring layers in each of which the conductive pattern is arranged is larger directly under the second electrode than directly under the first electrode.

19. An inspection apparatus for a semiconductor device, comprising:
a probe card for bringing, when electrical characteristics of an integrated circuit formed in a chip region of a semiconductor wafer are inspected, a plurality of measuring needles into contact with a plurality of electrodes arranged in the chip region in a state where the electrodes are electrically coupled to the integrated circuit,
wherein the measuring needles includes:
a first measuring needle that contacts a first electrode of the electrodes at a first needle pressure; and
a second measuring needle that contacts a second electrode of the electrodes at a second needle pressure larger than the first needle pressure, and
wherein the thickness of the second measuring needle is larger than that of the first measuring needle.

20. The inspection apparatus for a semiconductor device according to claim 19,
is wherein a protrusion length of the second measuring needle protruding from the probe card is larger than that of the first measuring needle protruding from the probe card.
